(19) United States
(12) Patent Application Publication
(10) Pub. No.: US 2005/0238044 A1
(43) Pub. Date: Oct. 27, 2005

(54) System and method for utility data collection

(76) Inventors: Christopher L. Osterloh, Waseca, MN (US); Neil R. Hovelsrud, Waseca, MN (US)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(21) Appl. No.: 11/114,940

(22) Filed: Apr. 26, 2005

Related U.S. Application Data
(60) Provisional application No. 60/565,289, filed on Apr. 26, 2004.

(51) Int. Cl. H01L 21/336; H04L 12/43

(52) U.S. Cl. 370/460

(57) ABSTRACT

An automatic meter reading fixed communication network for collecting data generated by a plurality of metering devices located within a geographic area, and a method for collecting data generated by a plurality of metering devices located within a geographic area. The network includes a plurality of endpoint devices, at least one relay device, a central radio device, and a head-end station for effecting wirelessly collection and communication of consumption data. A method of optimizing communications between network devices is also disclosed.

### RELATED APPLICATIONS AND CLAIM TO PRIORITY

This application claims priority to U.S. Provisional Patent Application No. 60/565,289, filed on Apr. 26, 2004, and entitled “SYSTEM AND METHOD FOR UTLITY DATA COLLECTION,” which is herein incorporated by reference in its entirety.

### FIELD OF THE INVENTION

The present invention relates generally to radio frequency (RF) communication systems, and more particularly to RF communication architectures used in advanced automatic meter reading (AMR) devices.

### BACKGROUND OF THE INVENTION

Automatic meter reading (AMR) systems are generally known in the art. Utility companies, for example, use AMR systems to read and monitor customer meters remotely, typically using radio frequency (RF) and other wireless communications. AMR systems are favored by utility companies and others who use them because they increase the efficiency and accuracy of collecting readings and managing customer billing. For example, utilizing an AMR system for the monthly reading of residential gas, electric, or water meters eliminates the need for a utility employee to physically enter each residence or business where a meter is located to transcribe a meter reading by hand.

There are two general ways in which current AMR systems are configured, fixed networks and mobile networks. In a fixed network, endpoint devices at meter locations communicate with readers that collect readings and data using RF communication. There may be multiple fixed intermediate readers, or relays, located throughout a larger geographic area on utility poles, for example, with each endpoint device associated with a particular reader and each reader in turn communicating with a central system. Other fixed systems utilize only one central reader with which all endpoint devices communicate. In a mobile network, a handheld unit or otherwise mobile reader with RF communication capabilities is used to collect data from endpoint devices as the mobile reader moves from place to place. The differences in how data is reported up through the system and the impact that has on number of units, data transmission collisions, frequency and bandwidth utilization has resulted in fixed network AMR systems having different communication architectures than mobile network AMR systems.

AMR systems can include one-way, one-and-a-half-way, or two-way communications capabilities. In a one-way system, an endpoint device typically uses a low power count down timer to periodically turn on, or “bubble up,” in order to send data to a receiver. One-and-a-half-way AMR systems include low power receivers in the endpoint devices that listen for a wake-up signal which then turns the endpoint device on for sending data to a receiver. Two-way systems enable two way command and control between the endpoint device and a receiver/transmitter. Because of the higher power requirements associated with two-way systems, two-way systems have not been favored for residential endpoint devices where the need for a long battery life is critical to the economics of periodically changing out batteries in these devices.

It would be desirable to provide for a fixed AMR system that had a communication architecture capable of efficiently supporting two way communications, while also permitting the flexibility of configuring the mobile AMR system to utilize different initiation protocols and to provide the capability of working in both a fixed network and a mobile network AMR system.

### SUMMARY OF THE INVENTION

The invention substantially meets the aforementioned needs of the industry, in particular by providing a system and method of collecting data by an AMR system that allow for the storage and transfer of meter readings and other data to eliminate the need to physically visit a remote endpoint device and connect directly to the endpoint device for the collection of data.

In one embodiment, a ring network for an automatic meter reading fixed communication network for collecting data generated by a plurality of metering devices located within a geographic area comprises a plurality of fixed-location endpoint devices, a fixed central radio device and a plurality of fixed relay devices. The plurality of fixed-location endpoint devices are positioned in the geographic area, each endpoint device coupled to a respective metering device and comprising a regenerative receiver to receive wake-up signals, a second receiver, and a transmitter to transmit signals representative of at least a portion of the data generated by the metering device and signals representative of a state of the endpoint device in an assigned time slot. The fixed central radio device is generally centrally located within the geographic area and operably connected to a head end station and has at least one transceiver to receive signals transmitted by at least one of an endpoint device and a relay device and to transmit signals representative of data generated by a metering device, status of at least one endpoint device, status of at least one relay device, wake-up signals, or any combination thereof. The fixed central radio device has an effective radio transmission inner radius in the ring network. The plurality of fixed relay devices are generally peripherally located within the geographic area and within the effective radio transmission radius of the fixed central radio device. There are fewer relay devices than endpoint devices. Each relay device has a regenerative receiver to receive wake-up signals, a second receiver to receive signals transmitted from at least one endpoint device, and a transmitter to transmit signals representative of the data generated by the metering device, a state of the endpoint device, and wake-up signals. The fixed relay devices has an effective radio transmission outer radius, such that the inner radius of the fixed central radio device and the outer radii of the plurality of fixed relay devices combine to provide an effective radio frequency coverage for the geographic area of the ring network. In another embodiment, the endpoint device is integrated into the metering device as a single device.

In one embodiment of an automatic meter reading communication network, a method for collecting data generated by a plurality of metering devices located within a geographic area comprises the steps of, for each of a plurality of fixed endpoint device coupled to a respective metering device, transitioning from a low-consumption mode to an active mode in an assigned time slot and wirelessly transmitting signals representative of at least a portion of the data generated by the metering device for that endpoint device in an assigned time slot; for at least one of a plurality of relay devices, transitioning from a low-consumption mode to an active mode in an assigned time slot and wirelessly receiving signals transmitted by at least one endpoint device; for a central radio device, wirelessly receiving the signals transmitted by at least one relay device and the signals transmitted by at least one endpoint device, and wirelessly transmitting signals representative of at least a portion of the data generated by the metering device for that endpoint device to a head-end station; and for a head-end station, wirelessly receiving the signals transmitted by the central radio device, decoding the signals, and storing data representative of at least a portion of the decoded signals in a database. The method can also comprise steps for optimizing a communication path to an endpoint device.

The above summary of the present invention is not intended to describe each illustrated embodiment or every implementation of the present invention. The figures and the detailed description that follow more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 is an exemplary diagram of a coverage cell of a fixed AMR system in accordance with an embodiment of the present invention.

FIG. 2 is an exemplary timing diagram of communications in a fixed AMR system in accordance with an embodiment of the present invention.

FIG. 3 is an exemplary slot timing diagram in accordance with one embodiment of the present invention.

FIG. 4 is a flowchart of an installation process according to one embodiment of the invention.

FIG. 5 is a flowchart of a path determination process according to one embodiment of the invention.

FIG. 6 is a flowchart of endpoint programming according to one embodiment of the invention.

FIG. 7 is a flowchart of endpoint programming according to one embodiment of the invention.

FIG. 8 is an exemplary automatic frequency control block diagram in accordance with one embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION OF THE INVENTION

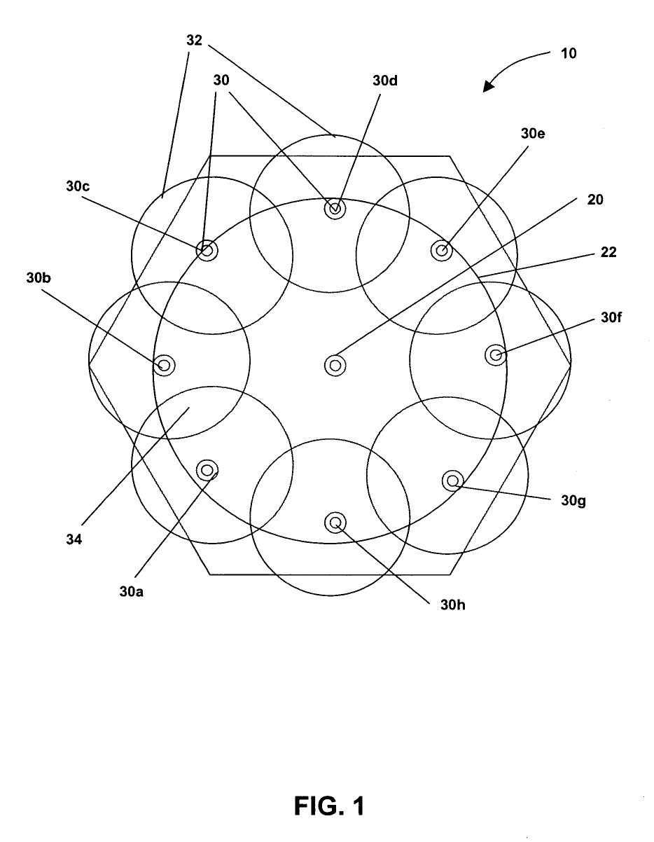

Preferred embodiments of the fixed network AMR system and method of the invention provide two-way communication capabilities in a locally geographically distributed environment. The invention can be more readily understood by reference to FIGS. 1-8, the appendices, and the following description. While the present invention is not necessarily limited to such an application, the invention will be better appreciated using a discussion of example embodiments in such a specific context.

FIG. 1 is an exemplary diagram of a coverage cell 10 of a fixed AMR system. Coverage cell 10 includes a central device 20 having an associated RF coverage radius 22. At an outer communicative edge of radius 22 are a plurality of relay devices 30, each having associated relay coverage radii 32. The combination of radii 22 and 32 blankets cell 10 with a predictable probability of wireless communicative success with any endpoint device located within radii 22 and 32.

Radii 22 and 32 can vary according to geographic and physical features and other factors affecting wireless communications, as will be appreciated by those skilled in the art. A typical area in which the system can be implemented will comprise areas of varied densities, including single- and multi-family homes, apartment complexes, residential medical facilities, educational centers, and areas of commercial and industrial zoning. These densities and uses will affect communication between the various devices 20 and 30 and the endpoint devices.

For example, an endpoint device located in close geographic proximity to central device 20 and within associated coverage radius 22 communicates directly with central device 20. An endpoint device located at the geographic periphery of coverage cell 10 yet within one of coverage radii 32 associated with a particular relay device 30 can communicate with central device 20 via associated relay device 30. An endpoint device located in an area of overlapping coverage 34 can communicate with either of the relevant relay devices 30a and 30b, or directly with central device 20, depending upon, for example, which device 30a, 30b, or 20 provided the clearest communication; which device 30a, 30b, or 20 had the fewest number of endpoint devices already associated with it; or some other factor.

As depicted in FIG. 1, coverage cell 10 is configured as an approximate hexagon for exemplary determinations of area and endpoint device density. RF coverage and hopping analyses will use circles. It can be shown that the area of a hexagon is:
Area=12*(r*cos 30*r*sin 30)/2
Area=3*cos 30*r\hat{ }2, where r is the radius of cell 10
Area=2.598*r\hat{ }2

For example, assume for purposes of this exemplary analysis that there is one residential endpoint device for each approximately 33,508 square feet. While this number can and will vary in specific implementations and installations of the system, it serves here as a starting point of one example. TABLE 1 below shows the correlation between the number of meters in one cell 10 and the radius of cell 10.

TABLE 1

| RADIUS IN | AREA IN | AREA IN | NUMBER OF |
|---|---|---|---|
| FEET | SQUARE FEET | SQUARE MILES | METERS/CELL |
| 200 | 103,920 | 0.0037 | 3 |
| 300 | 233,820 | 0.0084 | 7 |
| 400 | 415,680 | 0.0149 | 12 |
| 500 | 649,500 | 0.0233 | 19 |
| 600 | 935,280 | 0.0335 | 28 |
| 700 | 1,273,020 | 0.0457 | 38 |
| 800 | 1,662,720 | 0.0596 | 50 |
| 900 | 2,104,380 | 0.0755 | 63 |
| 1000 | 2,598,000 | 0.0932 | 78 |
| 1100 | 3,143,580 | 0.1128 | 94 |
| 1200 | 3,741,120 | 0.1342 | 112 |
| 1300 | 4,390,620 | 0.1575 | 131 |
| 1400 | 5,092,080 | 0.1827 | 152 |
| 1500 | 5,845,500 | 0.2097 | 174 |
| 1600 | 6,650,880 | 0.2386 | 198 |
| 1700 | 7,508,220 | 0.2693 | 224 |
| 1800 | 8,417,520 | 0.3019 | 251 |
| 1900 | 9,378,780 | 0.3364 | 280 |
| 2000 | 10,392,000 | 0.3728 | 310 |
| 2100 | 11,457,180 | 0.4110 | 342 |
| 2200 | 12,574,320 | 0.4510 | 375 |

Within a particular fixed network system, variations introduced related to geography, density, and types of meters should be considered with respect to signal propagation. Exemplary path loss equations are used for the loss between different types of environments. The equations each have a respective breakpoint at which the loss changes from a free space loss to a higher exponent loss.

Shown below are basic loss equations and a table showing the amount of loss for a given distance at a frequency of about 1430 MHz rounded to the nearest approximately 0.1 dB. The heights of antennas for the various endpoint devices, relay devices 30, and central device 20 used for these exemplary calculations include about twenty-five (25) feet to about 1.5 feet, about twelve (12) feet to about 1.5 feet, about six (6) feet to about 1.5 feet, about twenty-five (25) feet to about five (5) feet, about twelve (12) to about five (5) feet, and about six (6) to about five (5) feet. The heights of 1.5 feet and five (5) feet are used to simulate the actual heights of gas and electric meter endpoint devices and the twelve (12) and six (6) foot heights are used to simulate the heights of relay devices 30. These heights are only approximate and exemplary of one embodiment of the system of the invention. The heights can vary in actual system implementations according to a variety of factors recognized by those skilled in the art.

The following equations primarily describe the path losses (PL) after the breakpoint:
PL=10*Loss Exp*log(Distance in feet)+loss intercept (for distance>break point)

Path Loss Equations for Exemplary Gas Meters
PL=10*4.7917*log(Distance)−28.0 for distance>100 feet and 25-1.5 antennas
PL=10*5.6252*log(Distance)−49.228 for distance>150 feet and 12-1.5 antennas
PL=10*5.5619*log(Distance)−45.999 for distance>150 feet and 6-1.5 antennas

Path Loss Equations for Electric Meters
PL=10*4.3468*log(Distance)−17.346 for distance>200 feet and 25-5 antennas
PL=10*5.2635*log(Distance)−40.691 for distance>180 feet and 12-5 antennas
PL=10*5.3915*log(Distance)−42.678 for distance>180 feet and 6-5 antennas

TABLE 2

| | FREE | GAS | GAS | GAS | ELECTRIC | ELECTRIC | ELECTRIC |
|---|---|---|---|---|---|---|---|
| | SPACE | 25-1.5 | 12-1.5 | 6-1.5 | 25-5 | 12-5 | 6-5 |
| BREAKPOINT | 1 | 100 | 150 | 150 | 200 | 180 | 180 |
| IN FEET | | | | | | | |
| Loss | 2 | 4.7917 | 5.6252 | 5.5619 | 4.3468 | 5.2635 | 5.3915 |
| EXPONENT | | | | | | | |
| Loss INTER. | | −28.000 | −49.228 | −45.999 | −17.346 | −40.691 | −42.678 |
| DISTANCE IN | PL | PL | PL | PL | PL | PL | PL |
| FEET | IN DB | IN DB | IN DB | IN DB | IN DB | IN DB | IN DB |
| 100 | 65.0 | NA | NA | NA | NA | NA | NA |
| 200 | 71.0 | 82.3 | 80.3 | 82.0 | NA | 80.4 | 81.4 |
| 300 | 74.5 | 90.7 | 90.3 | 91.8 | 90.3 | 89.7 | 90.9 |
| 400 | 77.0 | 96.7 | 97.3 | 98.7 | 95.8 | 96.3 | 97.6 |
| 500 | 79.0 | 101.3 | 102.8 | 104.1 | 100.0 | 101.4 | 102.8 |
| 600 | 80.6 | 105.1 | 107.2 | 108.5 | 103.4 | 105.5 | 107.1 |
| 700 | 81.9 | 108.3 | 111.0 | 112.2 | 106.3 | 109.1 | 110.7 |
| 800 | 83.1 | 111.1 | 114.2 | 115.5 | 108.8 | 112.1 | 113.8 |
| 900 | 84.1 | 113.6 | 117.1 | 118.3 | 111.1 | 114.8 | 116.6 |
| 1000 | 85.0 | 115.8 | 119.7 | 120.9 | 113.1 | 117.2 | 119.1 |
| 1100 | 85.8 | 117.7 | 122.0 | 123.2 | 114.9 | 119.4 | 121.3 |
| 1200 | 86.6 | 119.5 | 124.2 | 125.3 | 116.5 | 121.4 | 123.3 |
| 1300 | 87.3 | 121.2 | 126.1 | 127.2 | 118.0 | 123.2 | 125.2 |
| 1400 | 87.9 | 122.8 | 127.9 | 129.0 | 119.4 | 124.9 | 126.9 |
| 1500 | 88.5 | 124.2 | 129.6 | 130.7 | 120.7 | 126.5 | 128.6 |
| 1600 | 89.1 | 125.5 | 131.2 | 132.2 | 121.9 | 128.0 | 130.1 |
| 1700 | 89.6 | 126.8 | 132.7 | 133.7 | 123.1 | 129.3 | 131.5 |
| 1800 | 90.1 | 128.0 | 134.1 | 135.1 | 124.2 | 130.7 | 132.8 |
| 1900 | 90.6 | 129.1 | 135.4 | 136.4 | 125.2 | 131.9 | 134.1 |
| 2000 | 91.0 | 130.2 | 136.6 | 137.6 | 126.1 | 133.1 | 135.3 |
| 2100 | 91.4 | 131.2 | 137.8 | 138.8 | 127.1 | 134.2 | 136.4 |
| 2200 | 91.8 | 132.2 | 139.0 | 139.9 | 127.9 | 135.2 | 137.5 |
| 2300 | 92.2 | 133.1 | 140.1 | 141.0 | 128.8 | 136.3 | 138.6 |
| 2400 | 92.6 | 134.0 | 141.1 | 142.0 | 129.6 | 137.2 | 139.6 |
| 2500 | 93.0 | 134.8 | 142.1 | 143.0 | 130.4 | 138.2 | 140.5 |

The above path loss numbers calculated are only statistical. Variation in these numbers should also be considered. Three forms of variation include:
σ_{LN}=log normal variance in the path due to buildings, cars, etc.=about 8 dB
σ_{R}=variance in the path due to Ricean fading=about 3.3 dB
σ_{F}=variance in the path loss due to foliage=about 2.5 dB
σₜ=total variance in the path loss=(σ_{LN}²+σ_{R}²+σ_{F}²)^{1/2}=about 9.0 dB

The variance is used to calculate a link margin necessary to achieve a particular probability of success in communications between devices within cell 10. Two exemplary probabilities will be used, 80% and 95%. Using a table of Standard Normal Distribution, the 80% and 95% probability occur at z=0.84 and z=1.645, respectively. Link margin for any path can thus be found by multiplying σₜ=9.0 dB by z.
Link Margin (80%)=9.0*0.84=7.6 dB
Link Margin (95%)=9.0*1.645=14.8 dB

To determine cell coverage, several RF signal factors should be considered. Assume for purposes of this exemplary analysis that devices 30 and 20 and the endpoint devices use frequency-shift keying (FSK) modulation to transmit and receive in one mode of operation. This can vary in other modes, for example a two-step regenerative receiver mode, as shown below:
Sensitivity for central device 20:
   about −115 dBm for 0.01 frame error rate (FER)
Sensitivity for endpoint device/relay device 30:
   about −108 dBm for 0.01 FER
Sensitivity for regenerative mode for endpoint device/relay device 30:
   about −100 dBm for tone detect
Link Margin (80%): about 7.6 dB above PL
Link Margin (95%): about 14.8 dB above PL
Transmit Power for central device 20: about +30 dBm
Transmit Power for endpoint device/relay device 30: about +14 dBm
Antenna Gain of central device 20: about 3 dBi
Antenna Gain of endpoint device: about −3 dBi
Antenna Gain of relay device 30: about 0 dBi

Outbound Regenerative Mode (Values are Approximate)
Path Loss for 80% (7.6 dB) central device 20 to endpoint device=+30+3−(−100)−3-7.6=122.4 dB
Path Loss for 80% (7.6 dB) central device 20 to relay device 30=+30+3−(−100)+0-7.6=125.4 dB
Path Loss for 80% (7.6 dB) relay device 30 to endpoint device=+14+0−(−100)−3-7.6=103.4 dB

Outbound FSK (Values are Approximate)
Path Loss for 80% (7.6 dB) central device 20 to endpoint device=+30+3−(−108)−3-7.6=130.4 dB
Path Loss for 95% (14.8 dB) central device 20 to endpoint device=+30+3−(−108)-3-14.8=123.2 dB
Path Loss for 95% (14.8 dB) central device 20 to relay device 30=+30+3−(−108)+0-14.8=126.2 dB
Path Loss for 80% (7.6 dB) relay device 30 to endpoint device=+14+0−(−108)−3-7.6=111.4 dB
Path Loss for 95% (14.8 dB) relay device 30 to endpoint device=+14+0−(−108)−3-14.8=104.2 dB

Inbound FSK (Values are Approximate)
Path Loss for 80% (7.6 dB) endpoint device to central device 20=+14−3−(−115)+3-7.6=121.4 dB
Path Loss for 95% (14.8 dB) endpoint device to central device 20=+14−3−(−115)+3-14.8=114.2 dB
Path Loss for 95% (14.8 dB) relay device 30 to central device 20=+14+0−(−115)+3-14.8=117.2 dB
Path Loss for 80% (7.6 dB) endpoint device to relay device 30=+14−3−(−108)+0-7.6=111.4dB
Path Loss for 95% (14.8 dB) endpoint device to relay device 30=+14−3−(−108)+0-14.8=104.2 dB

Observations relevant to system design and implementation, in particular how large cell 10 can or should be, can be made from the path loss table and link margin calculations. By way of example, assume that the antenna of central device 20 is about twenty-five (25) feet, the antenna of relay device 30 is about twelve (12) feet, a gas antenna is about 1.5 feet, and an electric antenna is about five (5) feet. See TABLE 3 below:

TABLE 3

| | | | Distance | Distance for |
|---|---|---|---|---|
| | Coverage | Path Loss | for Gas | Electric |
| | In % | In dB | In Feet | In Feet |
| Outbound central device 20 to endpoint | 80 | 122.4 | 1375 | 1640 |
| device WUT | | | | |
| Outbound central device 20 to relay | 80 | 125.4 | 2380 | 2380 |
| device 30 WUT | | | (est.) | (est.) |
| Outbound relay device 30 to endpoint | 80 | 103.4 | 517 | 547 |
| device WUT | | | | |
| Outbound central device 20 to endpoint | 80 | 130.4 | 2020 | 2500 |
| device FSK | | | | |
| Outbound central device 20 to endpoint | 95 | 123.2 | 1430 | 1710 |
| device FSK | | | | |
| Outbound central device 20 to relay | 95 | 126.2 | 2480 | 2480 |
| device 30 FSK | | | (est.) | (est.) |
| Outbound relay device 30 to endpoint | 80 | 111.4 | 717 | 775 |
| device FSK | | | | |
| Outbound relay device 30 to endpoint | 95 | 104.2 | 535 | 565 |
| device FSK | | | | |
| Inbound endpoint device to central device | 80 | 121.4 | 1315 | 1555 |
| 20 FSK | | | | |
| Inbound endpoint device to central device | 95 | 114.2 | 927 | 1060 |
| 20 FSK | | | | |
| Inbound relay device 30 to central device | 95 | 117.2 | 1500 | 1500 |
| 20 FSK | | | (est.) | (est.) |
| Inbound endpoint device to relay device | 80 | 111.4 | 717 | 775 |
| 30 FSK | | | | |
| Inbound endpoint device to relay device | 95 | 104.2 | 535 | 565 |
| 30 FSK | | | | |

Note from the above that the inbound FSK data from the endpoint device to central device 20 is the weakest link in this example. Note also that gas meter coverage area is smaller because the antenna is only about 1.5 feet above the ground versus the electric meter's approximately five (5) feet. Therefore, if cell 10 is designed for the worst-case gas meter coverage area, the electric meters will also be incorporated.

In this example, relay devices 30 are placed about 1500 feet from the center of cell 10. The outbound WUT/data from central device 20 will talk for approximately 1500 feet directly to endpoint devices or relay devices 30. Relay devices 30 will extend that information another 500 feet or more to endpoint devices at the outer edges of cell 10. For endpoint devices that are RF shadowed, another relay device 30 can be added as needed. The combination of central device 20 to endpoint device or central device 20 to the relay device 30 to endpoint device will be extended out to about 2000 feet or more. This process is repeated in reverse during the in-bound portion of a read cycle. Because endpoint devices can talk directly to central device 20 or a relay device 30, the probability that the endpoint devices at the cell's 10 outer limits can talk back successfully to at least one device 20 or 30 is greatly increased. Thus, coverage in a 2000-foot cell 10 could include about 310 gas or electric meters under the umbrella of central device 20.

When central device 20, a plurality of relay devices 30, and a plurality of endpoint devices have been installed in a cell 10 and that all relay devices 30 are able to communicate with central device 20. Each endpoint device and relay device 30 includes a regenerative receiver, a FSK receiver, and a FSK transmitter tuned to cell 10's channel.

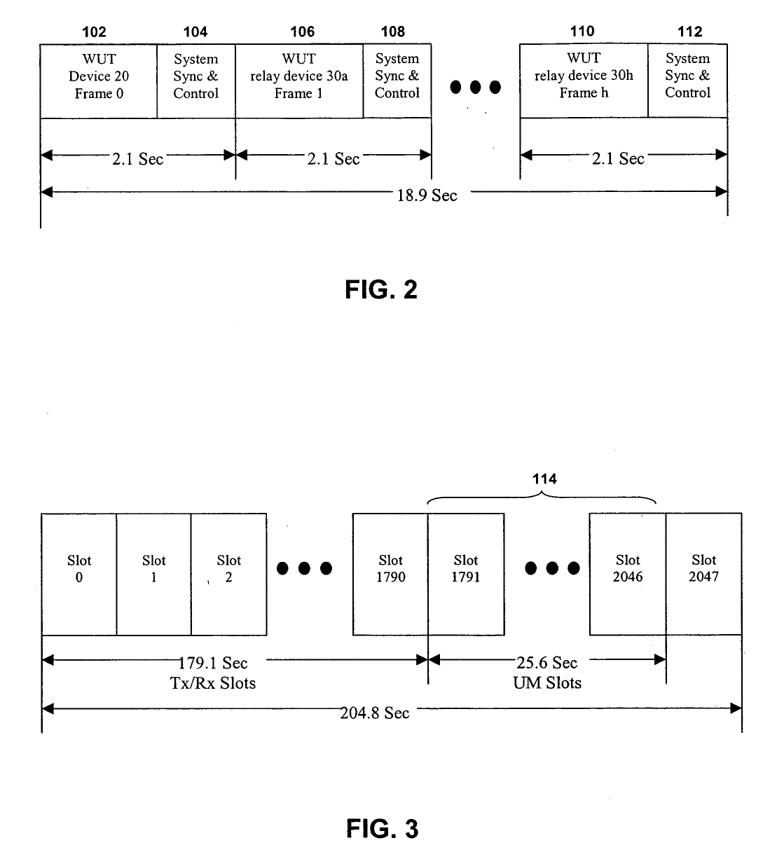

Referring to FIGS. 1 and 2, central device 20 receives a command from the Head-End (HE), which will typically be a utility control or management center, through a Wide Area Network (WAN). Central device 20 then sends out an approximately two-second WUT (wake-up tone) 102 on cell 10's channel to the regenerative receivers. This wakes up relay devices 30 and some or all of the endpoint devices, which in turn activate their FSK receivers. During the “on” portion of the WUT, FSK data is sent out with the number of WUT “on” periods left before sync and control information, plus the cell number. The endpoint device and relay devices 30 then go into sleep mode until the sync and control slot 104 to conserve current. Central device 20 then sends FSK sync and control data to relay devices 30 and the endpoint devices after the devices wake up again. The sync information is used to reset the real time clock (RTC) of each device to enable each device to transmit and receive with only a small error in specific time slots that follow.

After sync and control sequence 104, the endpoint devices and relay devices 30 go into sleep mode again until their assigned time slots. FIG. 1 depicts only eight relay devices 30 (30a-30h), but a larger number, for example up to about thirty-one (31) relay devices 30 in one preferred embodiment, can be handled in the protocol and cell 10 with appropriate extension of the time sequence.

After the WUT and sync time periods 102 and 104, relay device 30 sends out the same WUT/sync sequence, such as sequences 106 and 108 by relay device 30a and sequences 110 and 112 for relay device 30h, and wakes up the endpoint devices in its coverage area to establish a better communicative path to the endpoint devices than that directly from central device 20 (refer to FIG. 1). This process repeats until all eight relay devices 30 have transmitted WUT sequences.

The endpoint devices then begin responding to central device 20 or relay devices 30 in assigned time slots. If an endpoint device is assigned to a particular relay device 30, that relay device 30 will wake up during that endpoint device's time slot, receive data transmitted by the endpoint device, and relay the data to central device 20 in a later assigned time slot. This sequence continues until all endpoint devices have transmitted. In one example embodiment, up to about 1790 time slots of about 100 milliseconds each are available for data. At the end of the data slots are 256 slots for Unsolicited Messages (UM). UMs can be global, central device 20, relay device 30, or reserved, and will be described in a later section. This total sequence takes about 223.7 seconds for cell 10 having eight (8) relay devices 30a-30h. A similar sequence will take about 272 seconds for a cell with thirty-one (31) relay devices 30. It is estimated that approximately 1000 or more endpoint devices could be read during this time. If needed, additional data slots could be added.

Several wake-up tones can be set as default as shown below to accommodate a variety of data collection devices and create selectively hybrid systems. In one exemplary embodiment, some or all of the following wake-up tones can be set to increase the communicative options available for collecting data, although the wake-up tones and collection devices can vary in other preferred embodiments of the invention:
0—Mobile Vehicle System
1—Mobile Hand-Held System
2—Relay Device 30 Wake-Up
3—Endpoint Device Wake-Up Group A
4—Endpoint Device Wake-Up Group B
5—Endpoint Device Wake-Up Group C

A mobile vehicle system tone (0) causes the endpoint devices, and preferably not relay devices 30, to wake up and transmit a consumptive data message in a slot assigned to the device by a mobile collector, for example a data collection unit mounted or housed in a van or other vehicle. The mobile collector can therefore be used as needed or desired to conveniently collect supplementary, missed, or other data readings from a particular endpoint device or a plurality of endpoint devices.

A hand-held tone (1) causes the endpoint devices, but not relay devices 30, to wake up and transmit a consumptive data message in a slot assigned to it by a hand-held collector. Similar to the previously described mobile collector, a hand-held collector can be used as needed or desired to collect readings in a variety of situations, such as when an endpoint device reading by central device 20 or relay device 30 was missed or failed, or when a mid-cycle reading is needed. A user, whom may be a utility employee, walks or otherwise brings the hand-held collector within communicative range of the endpoint device to collect data.

In one embodiment, a relay device (2) wake-up tone wakes up only a relay device 30, not an endpoint device. Relay device 30 is then active to receive a command.

The endpoint device wake-up group tones (3-5) wake up both relay devices 30 and endpoint devices to receive a communication. The communication can be a read command; a communication to register a newly installed device when building a cell; a communication or command to register, initiate, or test a replaced or serviced device; a device programming command; an instruction to a device to turn on a switch, for example in telemetry applications; and other similar commands, communications, requests, and instructions. In one embodiment, the endpoint device or relay device 30 comprises an application-specific integrated circuit (ASIC) RF detect/tone detect chip that can be programmed to accept up to eight tones. In other embodiments, chips capable of accepting more or fewer tones can be used.

A synchronization and control communication between central device 20 and endpoint devices, central device 20 and relay devices 30, and relay devices 30 and endpoint devices is preferably 100 milliseconds long at about 4.8 kbps in one embodiment of the invention. The communication begins with five (5) milliseconds of “dead” time, followed by 10 milliseconds of synchronization, start/calibrate RTC, in one embodiment. Frame ID and the number of relay devices 30 in cell 10 comprise ten (10) bits and are followed by a 32-bit time stamp. Next, global flags and commands comprise 24 bits in this exemplary embodiment, with fifty-six (56) bits held in reserve, to be assigned later. A 32-bit ID and 16-bit vector can be sent to up to four (4) devices in one embodiment to tell the devices to which transmit/receive slot to go for downloaded data. A 16-bit cyclic redundancy check (CRC16) preferably ends the data string, with 15 milliseconds of synchronization information sent to complete the start/calibration of the RTC.

Referring to FIG. 3, UM slots 114 are slots 1791 to 2046, with slots 1791 and 1792 as global UM slots in normal mode, in one preferred embodiment. Global UM slots are used most frequently during the installation and building of cell 10, although the slots can also be used at other times and for other purposes. During installation and building, global UM slots may be expanded to sixteen (16) slots. Both central device 20 and relay devices 30 listen during global UM slots.

Central device 20 UM slots are slots 1793 to 1825 in one preferred embodiment. The endpoint devices in cell 10 transmit to central device 20 on the odd slots in this range in a random fashion. If central device 20 hears a particular endpoint device, device 20 transmits a confirmation in the next slot back to the listening endpoint device. Up to sixteen (16) Ums can be received by central device 20 during any read sequence in one embodiment.

Relay device 30 UM slots are preferably slots 1826 to 1981. These slots are divided into thirty-one (31) blocks of five slots each. An endpoint device transmits in a random fashion in one of the first two slots to a relay device 30 to which the endpoint device is assigned. If relay device 30 receives the transmission, relay device 30 simultaneously sends the UM to central device 20 and back to the endpoint device sending the UM. Central device 20 sends a confirmation message back to relay device 30 in the fifth slot. This continues for the total number of relay devices 30 in cell 10. Reserved slots are assigned from slot 1982 to slot 2046 in one embodiment, with slots 0 and 2047 reserved for quiet time and to listen to the noise floor of the system.

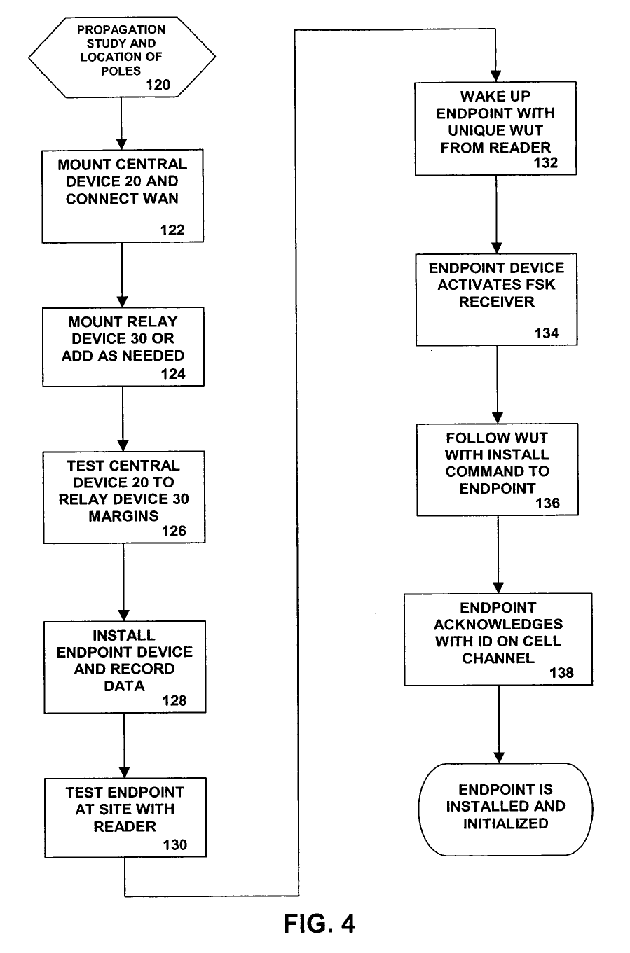

An installation and general configuration process for a fixed AMR system according to one embodiment of the invention is depicted in FIG. 4. After an initial propagation study and pole location determination at step 120, central device 20 is mounted and connected to the WAN at step 122. At step 124, relay devices 30 are mounted, although these devices 30 can also be added as needed as cell 10 is built. At step 126, central device 20 to relay device 30 communication margins are tested. Endpoint devices can then be installed and associated data, including latitude and longitude location and other information, recorded at step 128, then tested on-site at step 130 using a hand-held reader or other mobile device. Each endpoint device is sent a unique WUT at step 132 and in response activates its FSK receiver at step 134. At step 134, the WUT is followed by an install command from the reader to the endpoint device. If the endpoint acknowledges the command by transmitting its identification on the cell channel at step 138, the endpoint is successfully installed and initialized.

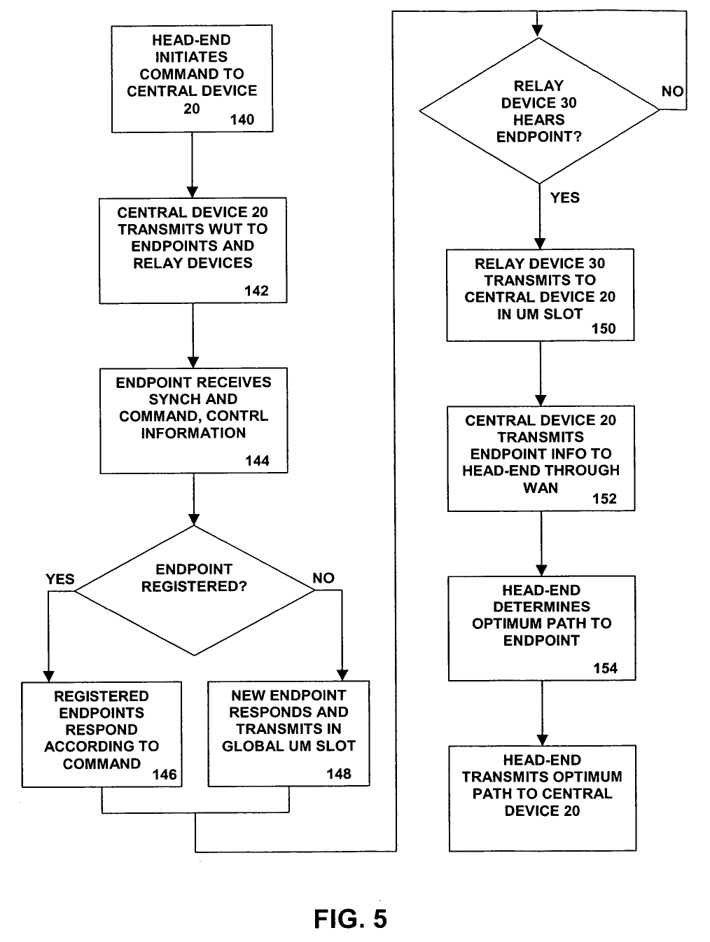

A preferred or optimal path to any endpoint device can be determined and set during the installation process, as depicted in FIG. 5. During a normal read cycle, the endpoint device hears a WUT from either central device 20 or a relay device 30. For example, in one embodiment after a head-end initiates a command to central device 20 at step 140, central device 20 transmits a WUT to endpoint devices and relay devices 30 within cell 10 at step 142. The endpoint device receives synchronization, and command and control information, and then goes into low current sleep mode at step 144. If the endpoint device is registered, the device will later respond according to command at step 146. If the device is unregistered, at step 148 the device will remain in sleep mode until the global UM slots. Upon wake-up in either situation, the endpoint device transmits a “Who Can Hear Me?” message. Central device 20 and each relay device 30 listen during these slots. If relay device 30 hears an endpoint device, device 30 transmits endpoint device information to central device 20 at step 150. These devices 20 and 30 record endpoint device identification and received signal strength indicator (RSSI) information that is sent to the head-end at step 152 for determination of the optimal route at step 154. This information can be sent directly from central device 20 or through one of the relay devices 30. This relieves central device 20 of the task of solely determining optimum routes.

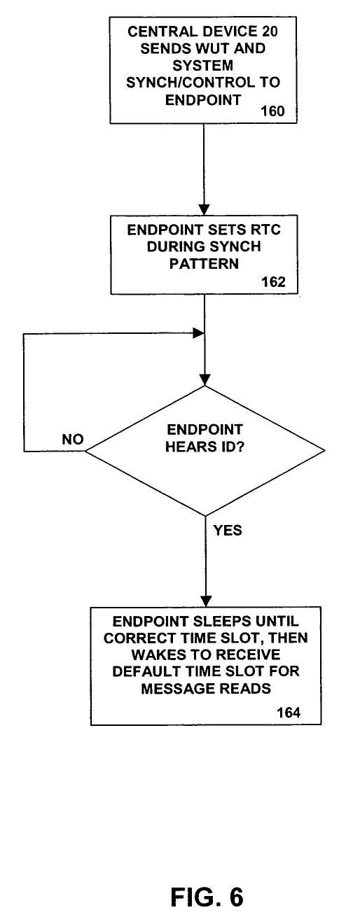

Referring to FIG. 6, during the next read cycle, the endpoint device just heard is called up in the identification vector of the system sync and control slots. At step 160, central device 20 sends WUT and system synch and command and control information to the endpoint device. The endpoint device then sets its RTC during the synch pattern at step 162 and goes into low current sleep mode, wakes up during the proper slot called out by the vector, and listens for its assigned transmit slot at step 164. Alternatively, the endpoint device can send back a confirmation in one of the later slots or wait for the next read cycle and transmit data as confirmation.

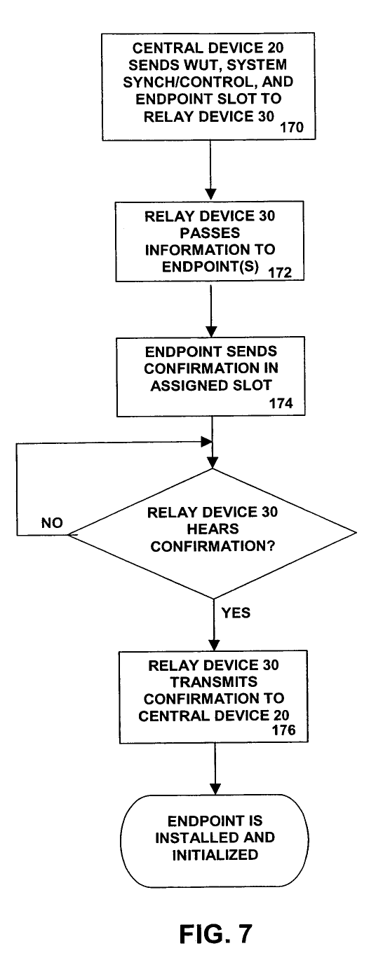

Referring to FIG. 7, the endpoint device receives information from relay device 30, rather than directly from central device 20. At step 170, central device 20 sends a WUT, system synchronization and control information, and endpoint slot information to relay device 30. Relay device 30 passes the information to the endpoint device at step 172 and the endpoint device transmits a confirmation in its assigned time slot at step 174. Relay device then transmits the confirmation to central device 20 at step 176.

There may be occasions when an endpoint device will lose synchronization with central device 20. In one embodiment, the endpoint device will wait for the next read cycle, wake up, have its RTC set, and respond in the proper slot to regain synchronization. An advantage of the system is that it is automatically synchronized during each read cycle by simply waking up and listening to the system sync and control time period.

Data packet speeds will depend primarily upon the endpoint device receive detection scheme, controller power, and current. In one embodiment, 4.8 kbps Manchester encoded data can be decoded in a relatively inexpensive controller. At this speed, about 480 bits or about 60 bytes of data could be sent during the 100 millisecond transmit and receive data slots. Data sent at about 4.8 kbps will also be decoded at an improved receive sensitivity than that sent at 9.6, 16.384, 19.2, or 38.4 kbps. This will help to enlarge cell 10 and improve the link margin.

Data packet sizes will dictate much of the system and communication timing. In one embodiment, and allowing about five (5) milliseconds at the beginning and end of the packet as dead time for RTC drift or some other minor error, the nominal size of the packet is about fifty-four (54) bytes. The packet preferably comprises three (3) bytes of bit/frame synchronization, four (4) bytes central device 20 identification, four (4) bytes of relay device identification, four (4) bytes endpoint device identification, three (3) bytes of command protocol, thirty-four (34) bytes of data, and two (2) bytes of CRC in one preferred embodiment. The thirty-four (34) bytes of data allow for seventeen (17) buckets of data at two (2) bytes/bucket in one embodiment. This enables one (1) hour and twenty-five (25) minutes worth of reads with a five (5) minute interval; four (4) hours and fifteen (15) minutes worth of reads with a fifteen (15) minute interval, and seventeen (17) hours worth of reads with a one (1) hour interval.

The bandwidth of the transmitters is a function of various factors, for example, the data rate, encoding technique, deviation, data wave shape generation, and base-band filtering, among others. Outbound and inbound data packets will preferably use a form of FSK modulation, such as minimum shift keying (MSK), Gaussian MSK (GMSK), or compatible four-level frequency modulation (C4FM), among others, with 4.8 kbps Manchester encoded data. Deviation can be about ±4.8 kHz in one embodiment.

Using Carson's rule, the approximate bandwidth (BW) is as follows:
BW=2*Peak Deviation+2*Base-band bandwidth
BW=2*4.8 kHz+2*4.8 kHz
BW=about 19.2 kHz

The bandwidth of the receivers is preferably as narrow as possible, consistent with phase-locked loop (PLL) reference crystal drift, range of automatic frequency control (AFC), and temperature drift of the IF filters, to provide the best sensitivity and range for the system. In one embodiment, receiver bandwidth may be about 20 kHz to about 25 kHz. To address adjacent channel rejection in all system devices, the channels are preferably spaced about 50 kHz apart. While potential exists for interference from another system in the local area of cell 10, the time and frequency of the reads should minimize the data packets lost.

Cell timing is important, as each endpoint device and relay device 30 in cell 10 needs to know when to come out of sleep mode and either transmit or receive in a specific time slot. The RTC is preferably running all the time, even during an endpoint device's low current sleep mode. The RTC and a counter in the device controller will instruct the FSK receiver when to turn on. Because the RTC clock must be relatively low frequency to keep the sleep mode current low and reduce battery consumption, a 32-kHz crystal will be used in one embodiment. The 32-kHz crystal can be a “BT” cut with parabolic TC curve having a reference setting at +25C in one preferred embodiment, although other crystals can also be used.

Over a temperature range of about −40C to about +85C, however, the crystal could move up to about −150 ppm. This translates to about −45 milliseconds in a 5-minute read period. This amount of time is about half of the 100 millisecond transmit and receive data slot and is therefore unacceptable. A proposed correction scheme is to use the synchronization at the beginning and end of the system sync and control slot is transmitted after the WUT as described above. The time between these two (2) synchronization bursts would calibrate the 32-kHz crystal and counter in the controller within about 15 ppm, reducing error in the Sminute read cycle wake-up error to less than five (5) milliseconds.

A combination of a special specification for the crystal and AFC in the receiver may be required in some embodiments. If the crystal of the PLL is called out to be ±10 ppm in a range of about −20C to about +70C, the crystal can then be about −30 ppm at about −40C and about +25 ppm at about +85C. Taking the worst case of −30ppm, the LO would be about −43kHz from the desired frequency. This is approaching two (2) channel bandwidths away. Accordingly, a tighter crystal could be called out and AFC used in the receiver.

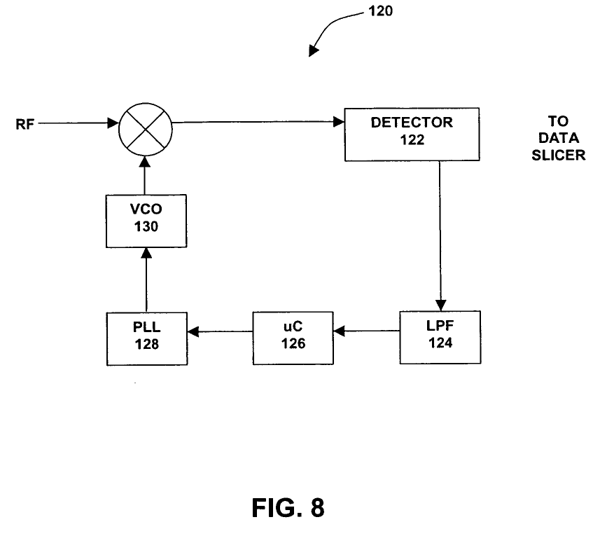

Referring to FIG. 8, an AFC loop 120 preferably starts during the WUT detection period. After the WUT is detected, the FSK receiver turns on. Since detector 122 has a component at DC that is representative of the carrier, the modulation is stripped away in a low pass filter (LPF) 124. This leaves the DC component, which is fed to a controller 126 A/D port where a voltage offset between the incoming carrier and a perfect carrier is measured. This differential is converted to a frequency error and then new numbers in the PLL fractional N divider 128. The new numbers are loaded, VCO 130 changes frequency in the LO, and the new IF is fed to detector 122 for another sampling. Because the fractional N divider resolution is about 500 Hz, the overall LO should be correctable to this level in a preferred embodiment.

The above preferably occurs during the WUT period before the system sync and control begins. This will center the IF and ensure the receiver has the best possible sensitivity. The offset in the fractional N dividers is also transferred to the transmit signal. This will ensure that the endpoint device is transmitting on the correct frequency, or within about 500 Hz. AFC loop 120 is used in relay device 30 to ensure that device 30 transmits on the correct frequency to the endpoint device.

Battery-powered devices within cell 10 can present power consumption issues that should be addressed to improve the efficiency of the system. For example, the overall costs associated with the system are greatly increased if system devices need to be frequently serviced in person in order to check and change out battery power supplies. In one preferred embodiment according to exemplary calculations and estimations, system devices are optimized to reduce current drain, providing a battery power source life of at least seven (7) years or more for a SAFT D LS 33600 cell in relay device 30. For relay devices 30 having less than ten (10) endpoint devices in a communicative umbrella, which infrequently send UMs, and with a cell read every approximately half-hour or hour, the same D-cell could last ten (10) years or more.

Therefore, the invention substantially meets the aforementioned needs of the industry, in particular by providing a system and method of operating AMR systems that allow for the storage and transfer of meter readings and other data to eliminate the need to physically visit a remote endpoint device and connect directly to the endpoint device for the collection of data.

In one preferred embodiment, the invention is directed to a system and method for meter reading of a fixed network that provides two-way communication between an endpoint device and a reader. The fixed network meter reading system and method of the present invention provide larger cell sizes than in previous fixed network meter reading systems, partly through the use of intermediate relay devices and cost-effective endpoint devices that consume less power.

In a related embodiment, the invention enables two-way communication in a fixed network meter reading system. In a series of communications between a central reader, a plurality of relays, and a plurality of endpoint devices associated with each of the plurality of relays, data requests and responses are exchanged between the endpoint devices and the relays, and subsequently the relays and the central reader. The central reader, plurality of relays, and plurality of endpoint devices are part of a fixed “ring” system distributed throughout a geographic area.

The invention may be embodied in other specific forms without departing from the spirit of the essential attributes thereof; therefore, the illustrated embodiments should be considered in all respects as illustrative and not restrictive, reference being made to the appended claims rather than to the foregoing description to indicate the scope of the invention.

1. A ring network for an automatic meter reading fixed communication network for collecting data generated by a plurality of metering devices located within a geographic area, the ring network comprising:
a plurality of fixed-location endpoint devices in the geographic area, each endpoint device coupled to a respective metering device and comprising a regenerative receiver to receive wake-up signals, a second receiver, and a transmitter to transmit signals representative of at least a portion of the data generated by the metering device and signals representative of a state of the endpoint device in an assigned time slot;
a fixed central radio device generally centrally located within the geographic area and operably connected to a head end station and comprising at least one transceiver to receive signals transmitted by at least one of an endpoint device and a relay device and to transmit signals representative of data generated by a metering device, signals related to a status of at least one endpoint device, signals related to a status of at least one relay device, wake-up signals, or any combination thereof, the fixed central radio device having an effective radio transmission inner radius; and
a plurality of fixed relay devices generally peripherally located within the geographic area and within the effective radio transmission radius of the fixed central radio device, there being fewer relay devices than endpoint devices, each relay device comprising a regenerative receiver to receive wake-up signals, a second receiver to receive signals transmitted from at least one endpoint device, and a transmitter to transmit signals representative of the data generated by the metering device, signals representative of a state of the endpoint device, and wake-up signals, the fixed relay devices having an effective radio transmission outer radius,
wherein the inner radius of the fixed central radio device and the outer radii of the plurality of fixed relay devices combine to provide an effective radio frequency coverage for the geographic area of the ring network.

2. The network of claim 1, wherein at least one endpoint device is communicatively assigned to a particular relay device.

3. The network of claim 2, wherein the relay device is adapted to wake up in the assigned time slot of the endpoint device.

4. The network of claim 1, wherein the network is adapted to operate in a licensed communication band.

5. The network of claim 4, wherein the communication band is about 1427 megahertz to about 1432 megahertz.

6. The network of claim 1, wherein the wake-up signals comprise a signal selected from the group consisting of a mobile vehicle system-initiated wake-up signal; a mobile hand-hand system-initiated signal; a relay device wake-up signal; and a group wake-up signal.

7. The network of claim 6, wherein the mobile vehicle system-initiated wake-up signal addresses only an endpoint device or group of endpoint devices.

8. The network of claim 6, wherein the mobile hand-held system-initiated signal addresses only an endpoint device or group of endpoint devices.

9. The network of claim 6, wherein the group wake-up signal addresses at least one endpoint device, at least one relay device, or any combination thereof, and wherein the group wake-up signal precedes a communication signal.

10. The network of claim 9, wherein the communication signal comprises a signal selected from the group consisting of a read command; a registration command; an initiation command; a test command; a programming command; and an instruction to activate a device.

11. The network of claim 6, wherein at least one endpoint device and at least one relay device comprise wake-up signal detection circuitry programmed to detect at least six wake-up signals.

12. The network of claim 1, wherein the transmitter of at least one fixed relay device is programmed to transmit in an assigned time slot.

13. The network of claim 12, wherein the transmitter is programmed by a signal received from the head-end station.

13. The network of claim 1, wherein the ring network is geographically positioned generally adjacent a plurality of other similar ring networks, all of which have a central radio device operably connected to the head end station.

14. The network of claim 13, wherein the central radio device of each ring network is programmed by a signal received from the head-end station to operate on a separate time slot from the adjacent ring networks.

15. An automatic meter reading fixed communication network for collecting data generated by a plurality of metering devices located within a geographic area, comprising:
a plurality of ring networks defined in the geographic area, each ring network located generally adjacent to at least one other ring network and comprising:
a plurality of fixed-location metering devices, each metering device comprising a regenerative receiver to receive wake-up signals, a second receiver, and a transmitter to transmit signals representative of at least a portion of the data generated by the metering device and signals representative of a state of the metering device in an assigned time slot;
at least one fixed relay device located within the geographic area, there being fewer relay devices than metering devices, each relay device comprising a regenerative receiver to receive wake-up signals, a second receiver to receive signals transmitted from at least one metering device, and a transmitter to transmit signals representative of the data generated by the metering device, signals representative of a state of the metering device, and wake-up signals; and
a fixed central radio device generally centrally located within the geographic area and comprising at least one transceiver to receive signals transmitted by at least one of a metering device and a relay device and to transmit signals representative of data generated by a metering device, signals related to a status of at least one metering device, signals related to a status of at least one relay device, wake-up signals, or any combination thereof; and
a head-end station operably coupled to communicate with the central radio device of each ring network.

16. In an automatic meter reading communication network, a method for collecting data generated by a plurality of metering devices located within a geographic area comprising:
for each of a plurality of fixed endpoint device coupled to a respective metering device, transitioning from a low-consumption mode to an active mode in an assigned time slot and wirelessly transmitting signals representative of at least a portion of the data generated by the metering device for that endpoint device in an assigned time slot;
for at least one of a plurality of relay devices, transitioning from a low-consumption mode to an active mode in an assigned time slot and wirelessly receiving signals transmitted by at least one endpoint device;
for a central radio device, wirelessly receiving the signals transmitted by at least one relay device and the signals transmitted by at least one endpoint device, and wirelessly transmitting signals representative of at least a portion of the data generated by the metering device for that endpoint device to a head-end station; and
for a head-end station, receiving the signals transmitted by the central radio device, decoding the signals, and storing data representative of at least a portion of the decoded signals in a database.

17. The method of claim 16, further comprising:
initiating a command by transmitting a signal from the head-end station to the central radio device;
wirelessly transmitting a wake-up signal by the central radio device to at least one of an endpoint device and a relay device responsive to the signal transmitted by the head-end station;
wirelessly transmitting a signal responsive to the wake-up signal by an endpoint device;
detecting, by a relay device, the signal transmitted by the endpoint device and determining from the signal an identification of the endpoint device;
transmitting the identification of the endpoint device to the head-end station via the central radio device by the relay device;
determining, by the head-end station, an optimum communication path to the endpoint device via at least one of the central radio device and a relay device; and
transmitting the optimum communication path from the head-end station to the central radio device.
